(19) United States
(12) Patent Application Publication
(10) Pub. No.: US 2014/0107926 A1
(43) Pub. Date: Apr. 17, 2014

(54) DISTANCE RELAY USING REAL TIME LIGHTNING DATA

(71) Applicant: Korea Electric Power Corporation, Seoul (KR)

(72) Inventors: Jung-Wook WOO, Daejeon (KR); Joo-Sik KWAK, Daejeon (KR); Dong-Jin KWEON, Daejeon (KR); Kyung-Tak KIM, Daejeon (KR); Kyo-Sun KOO, Daejeon (KR)

(73) Assignee: Korea Electric Power Corporation, Seoul (KR)

(21) Appl. No.: 14/133,401

(22) Filed: Dec. 18, 2013

Related U.S. Application Data
(63) Continuation-in-part of application No. 12/881,646, filed on Sep. 14, 2010.

(30) Foreign Application Priority Data
Sep. 29, 2009 (KR) 10-2009-0092383

(51) Int. Cl. G01R 31/08; G01W 1/00

(52) U.S. Cl. CPC G01R 31/08; G01W 1/00
USPC 702/4

(57) ABSTRACT

A distance relay apparatus, a distance relay processing system and a method for processing a distance relay are disclosed. In accordance with an embodiment of the present invention, the distance relay processing system, which controls a distance relay, includes a lightning managing apparatus, which generates comprehensive lightning information by using lightning detection information and in which the lightning detection information is provided by a lightning detector, and a distance relay apparatus, which generates fault occurrence information by determining a fault location of a power transmission line and generates fault analysis information by using the fault occurrence information and the comprehensive lightning information.

### CROSS-REFERENCE TO RELATED APPLICATIONS

This application claims the benefit of Korean Patent Application No. 10-2009-0092383, filed with the Korean Intellectual Property Office on Sep. 29, 2009, the disclosure of which is incorporated herein by reference in its entirety.

### BACKGROUND

1. Technical Field

The present invention relates to a distance relay apparatus, more specifically to a distance relay apparatus, a distance relay processing system and a method for processing a distance relay using lightning data.

2. Description of the Related Art

Recently, there has been an increased demand for power consumption due to the rapid growth of the industrial economy. During the peak summer season, the power consumption nearly approaches the maximum supply capacity of all available power plants, and thus cooperation by the citizens is sought on a national level. Due to the dramatic increase in electrical energy consumption caused by not only the densely populated cities but also the trends toward bigger size in various small-scale industries, large buildings and apartment complexes and the like, large capacity power transmission lines are supplied to the central part of a city.

This has increased the construction of underground power transmission lines and mixed power transmission lines, in which underground power lines and over-the-ground power lines are combined. In case an accident such as ground fault or lightning occurs in such power transmission lines, a relay apparatus, which blocks a fault zone, may be used.

As digital relay apparatuses using microprocessors are practically used to protect the power transmission lines with the increasingly larger and complicated power systems, today's relay apparatuses realize various and complicated technologies that could not be achieved by conventional analog protection relay apparatuses.

Among various transmission line protection apparatuses, a distance relay apparatus is most commonly used to control an electrical circuit by operating and opening or closing a contact according to the predetermined amount of electrical or physical quantity. That is, if a short circuit or ground fault occurs somewhere in the power transmission line or if an abnormal operation that has an adverse effect resulting in broken insulation occurs, the distance relay apparatus may quickly block the fault portion.

However, due to a location error, the conventional distance relay apparatus may not be able to accurately determine a fault location even though it is required to quickly determine and repair the fault location when the fault occurs by lightning.

### SUMMARY

The present invention provides a distance relay apparatus, a distance relay processing system and a method for processing a distance relay that can determine a fault location in power transmission line by using lightning data.

The present invention also provides a distance relay apparatus, a distance relay processing system and a method for processing a distance relay that can quickly determine a fault location in power transmission line accurately.

Also, the present invention provides a distance relay apparatus, a distance relay processing system and a method for processing a distance relay that can minimize an error in finding a fault location in power transmission line.

An aspect of the present invention features a distance relay processing system that controls a distance relay.

In accordance with an embodiment of the present invention, a distance relay processing system, which controls a distance relay, can include a lightning managing apparatus, which generates comprehensive lightning information by using lightning detection information and in which the lightning detection information is provided by a lightning detector, and a distance relay apparatus, which generates fault occurrence information by determining a fault location in a power transmission line and generates fault analysis information by using the fault occurrence information and the comprehensive lightning information.

The distance relay apparatus can generate an error value by comparing the fault occurrence information and the comprehensive lightning information and generate the fault analysis information by removing the error value from the fault occurrence information.

The distance relay apparatus can generate the fault occurrence information by analyzing a distance value provided from at least one of a plurality of relays that has determined the fault location in the power transmission line.

The comprehensive lightning information can include at least one of lightning time information, lightning location information and lightning current magnitude information.

The fault occurrence information can include at least one of transmission fault time information and transmission fault location information.

The lightning managing apparatus can generate the comprehensive lightning information by analyzing the lightning detection information provided by at least one of a plurality of lightning detectors that has detected lightning.

The lightning managing apparatus can transfer the comprehensive lightning information to the distance relay apparatus in each transmission time, which is a period of time for transferring the comprehensive lightning information to the distance relay apparatus and set by the lightning managing apparatus.

Another aspect of the present invention features a distance relay apparatus connected to a lightning managing apparatus.

In accordance with an embodiment of the present invention, a distance relay apparatus connected to a lightning managing apparatus can include a relay, which determines a fault location in a power transmission line, a generating unit, which generates fault occurrence information by using a result that is determined by the relay, and a parser, which generates fault analysis information by using comprehensive lightning information and the fault occurrence information. Here, the comprehensive lightning information is received from the lightning managing apparatus.

The parser can generate an error value by comparing the fault occurrence information and the comprehensive lightning information and generate the fault analysis information by removing the error value from the fault occurrence information.

The generating unit can generate the fault occurrence information by analyzing a distance value provided by at least one of a plurality of relays that has determined the fault location in the power transmission line.

The distance relay apparatus can also include a display, which displays the fault analysis information.

The comprehensive lightning information can include at least one of lightning time information, lightning location information and lightning current magnitude information, and the fault occurrence information can include at least one of transmission fault time information and transmission fault location information.

Another aspect of the present invention features a distance relay processing method for controlling a distance relay in a distance relay processing system.

In accordance with an embodiment of the present invention, a distance relay processing method for controlling a distance relay in a distance relay processing system can include generating fault occurrence information by determining a fault location in a power transmission line, generating comprehensive lightning information by using lightning detection information provided by a lightning detector, and generating fault analysis information by using the fault occurrence information and the comprehensive lightning information.

In the generating of the fault analysis information, an error value can be generated by comparing the fault occurrence information with the comprehensive lightning information, and the fault analysis information can be generated by removing the error value from the fault occurrence information.

The generating of the fault occurrence information can include receiving a distance value from at least one of a plurality of relays and generating the fault occurrence information by analyzing the distance value. Here, at least one of the relays determines a fault location in the power transmission line.

In the generating of the comprehensive lightning information, the comprehensive lightning information can be generated by analyzing the lightning detection information provided by at least one of a plurality of lightning detectors that has detected lightning.

The comprehensive lightning information can include at least one of lightning time information, lightning location information and lightning current magnitude information.

The fault occurrence information can include at least one of transmission fault time information and transmission fault location information.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a block diagram briefly illustrating a distance relay processing system in accordance with an embodiment of the present invention.

FIG. 2 is a block diagram illustrating a lightning managing apparatus of a distance relay processing system in accordance with an embodiment of the present invention.

FIG. 3 is a block diagram illustrating a distance relay apparatus of a distance relay processing system in accordance with an embodiment of the present invention.

FIG. 4 is a flowchart briefly illustrating a method for processing a distance relay in accordance with an embodiment of the present invention.

FIG. 5 is a flowchart illustrating, in detail, a method for processing a distance relay in accordance with an embodiment of the present invention.

FIG. 6 is an example illustrating a lightning detector and a relay in a distance relay processing system in accordance with an embodiment of the present invention.

FIG. 7 is an example illustrating a method for processing a distance relay in which a distance relay apparatus determines a fault location in accordance with another embodiment of the present invention.

### DETAILED DESCRIPTION

As the invention allows for various changes and numerous embodiments, certain embodiments will be illustrated in the drawings and described in detail in the written description. However, this is not intended to limit the present invention to particular modes of practice, and it is to be appreciated that all changes, equivalents, and substitutes that do not depart from the ideas and technical scope of the present invention are encompassed in the present invention. In the description of the present invention, certain detailed descriptions of related art are omitted when it is deemed that they may unnecessarily obscure the essence of the invention.

While such terms as “first” and “second,” etc., may be used to describe various components, such components may not be limited to the above terms. The above terms are used only to distinguish one component from another.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc. are intended to indicate the existence of the features, numbers, steps, operations, components, parts, or combinations thereof disclosed in the specification, and are not intended to preclude the possibility that one or more other features, numbers, steps, operations, components, parts, or combinations thereof may exist or may be added.

A distance relay apparatus, a distance relay processing system and a method for processing distance relay according to certain embodiments of the present invention will be described below in more detail with reference to the accompanying drawings. Those components that are the same or are in correspondence are rendered the same reference numeral regardless of the figure number, and redundant descriptions are omitted.

FIG. 1 is a block diagram briefly illustrating a distance relay processing system in accordance with an embodiment of the present invention.

Referring to FIG. 1, if a power transmission line has a fault due to lightning, a distance relay processing system 100 detects the fault and block the section with the fault. For this, the distance relay processing system 100 includes a lightning managing apparatus 200 and a distance relay apparatus 300.

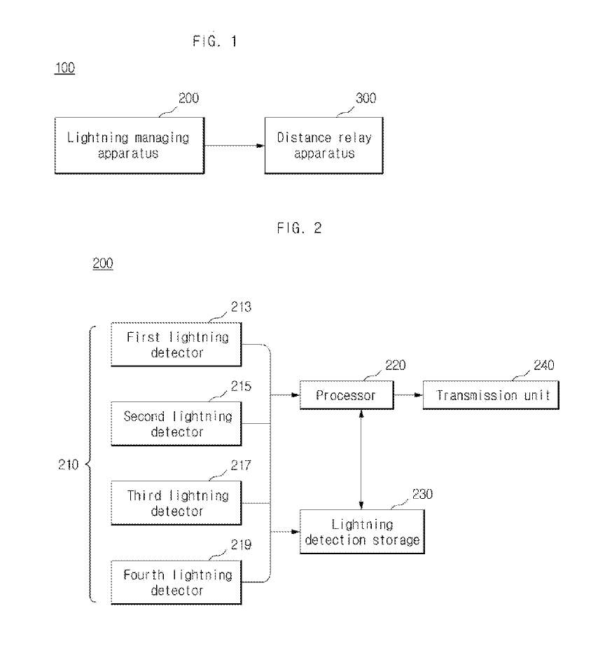

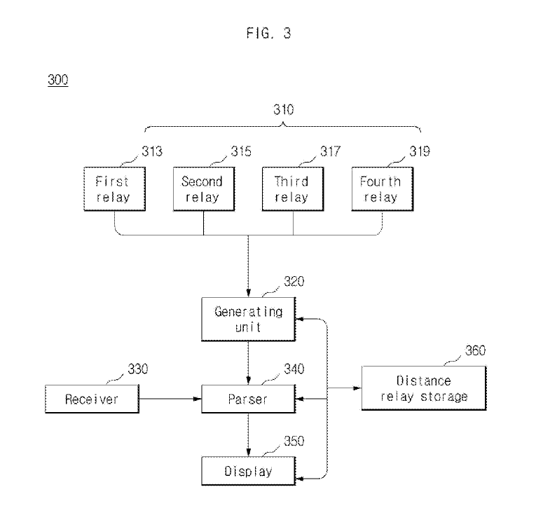

The lightning managing apparatus 200 is connected to the distance relay apparatus 300 and detects a location that is struck by lightning as it occurs. Also, the lightning managing apparatus 200 generates comprehensive lightning information by using the detected information. Then, the lightning managing apparatus 200 transmits the generated lightning integrated information to the distance relay apparatus 300. Here, the lightning managing apparatus 200 can transmit the lightning integrated information to the distance relay apparatus 300 by at least one of a wireless communication method and a wire communication method. The lightning managing apparatus 200 will be described in more detail with reference to FIG. 2.

The distance relay apparatus 300 is connected to the lightning managing apparatus 200 and determines a fault location if fault occurs in the power transmission line. The distance relay apparatus 300 generates fault occurrence information by using the determined fault location. The distance relay apparatus 300 generates fault analysis information by using the comprehensive lightning information received from the lightning managing apparatus 200 and the fault occurrence information. The distance relay apparatus 300 will be described in more detail with reference to FIG. 3.

FIG. 2 is a block diagram illustrating a lightning managing apparatus of a distance relay processing system in accordance with an embodiment of the present invention.

Referring to FIG. 2, the lightning managing apparatus 200 includes first to fourth lightning detectors 213, 215, 217 and 219, a processor 220, a lightning detection storage 230 and a transmission unit 240.

Each of the first to fourth lightning detectors 213, 215, 217 and 219 is located in a different place and detects lightning when it occurs. Hereinafter, the first to fourth lightning detectors 213, 215, 217 and 219 will be referred to as a lightning detector 210. The lightning detector 210 generates lightning detection information by detecting lightning when the lightning occurs in the detection zone. Then, the lightning detector 210 provides the generated lightning detection information to the processor 220. Here, the lightning detector 210 can provide the lightning detection information to the processor 220 by using a wireless communication method.

In FIG. 2, there are a total of 4 lightning detectors 210. It shall be apparent, however, that the present invention is not restricted to the total of 4 lightning detectors and can be implemented regardless of the number of the lightning detectors 210 as long as lightning can be detected.

The processor 220 is provided with the lightning detection information, which is provided from at least one of the lightning detectors 210, each of which detects lightning. The processor 220 generates comprehensive lightning information by analyzing and calculating the provided lightning detection information. Here, the comprehensive lightning information includes information about when lightning has struck, information about where lightning has struck and information about the magnitude of current in the lightning. The processor 220 controls the transmission unit 240 in such a way that the comprehensive lightning information is transferred to the distance relay apparatus 300.

Meanwhile, the processor 220 can set a transmission time for transferring information to the distance relay apparatus 300. The processor 220 can transfer the comprehensive lightning information to the distance relay apparatus 300 in each transmission time by controlling the transmission unit 240.

If lightning does not strike, the processor 220 can also generate lightning confirmation information regarding whether lightning has struck and transfer this information to the distance relay apparatus 300 through the transmission unit 240 in each transmission time.

The lightning detection storage 230 stores data that is required when detecting lightning or data that is generated by detecting the lightning. That is, the lightning detection storage 230 can store the lightning detection information, which is generated by the lightning detectors 210, and store the comprehensive lightning information, which is generated by the processor 220. Also, the lightning detection storage 230 can provide information that is required by the processor 220 and the transmission unit 240.

The transmission unit 240 is connected to a receiver 330 of the distance relay apparatus 300. The transmission unit 240 transfers the comprehensive lightning information, which is generated by the processor 220, to the receiver 330. Here, the transmission unit 240 can transfer the comprehensive lightning information to the receiver 330 either through a wireless communication method by being connected to the receiver 330 wirelessly or through a wire communication method by being connected to the receiver 330 with a wired connection. Meanwhile, the transmission unit 240 can transfer the lightning confirmation information to the receiver 330 of the distance relay apparatus 300.

FIG. 3 is a block diagram illustrating a distance relay apparatus of a distance relay processing system in accordance with an embodiment of the present invention.

Referring to FIG. 3, the distance relay apparatus 300 includes first to fourth relays 313, 315, 317 and 319, a generating unit 320, a receiver 330, a parser 340, a display 350 and a distance relay storage 360.

The first to fourth relays 313, 315, 317 and 319 determine whether a power transmission line that is connected to each of the first to fourth relays has a fault. Hereinafter, the first to fourth relays 313, 315, 317 and 319 will be referred to as a relay 310. The relay 310 generates a distance value by determining a fault location when the fault occurs in the power transmission line due to lightning. Then, the relay 310 provides the distance value to the generating unit 320. The relay 310 can provide the distance value to the generating unit 320 by a wireless communication method.

In FIG. 3, there are a total of 4 relays 310. It shall be apparent, however, that the present invention is not restricted to the total of 4 relays and can be implemented regardless of the number of the relays 310 as long as the fault in the power transmission line can be determined.

The generating unit 320 is provided with a distance value, which is provided from each of a plurality of relays 310 that has detected a fault in the power transmission line. The generating unit 320 analyzes and calculates the distance value and generates fault occurrence information. Here, the fault occurrence information includes time information on the fault in the power transmission line and location information on the fault in the power transmission line.

The receiver 330 is connected to the transmission unit 240 of the lightning managing apparatus 200 and receives the comprehensive lightning information. Here, the receiver 330 can receive the comprehensive lightning information from the transmission unit 240 either through a wire communication method by being connected to the transmission unit 240 with a wired connection or through a wireless communication method by being connected to the transmission unit 240 wirelessly. Meanwhile, the receiver 330 can receive the lightning confirmation information from the transmission unit 240.

The parser 340 generates fault analysis information by using the fault occurrence information and the comprehensive lightning information. That is, the parser 340 generates an error value by comparing the fault occurrence information with the comprehensive lightning information. The parser 340 generates the fault analysis information by removing the error value from the fault occurrence information. As such, since the fault occurrence information is generated by using the comprehensive lightning information, this can determine a more accurate location than a conventional method of determining a fault location in a power transmission line.

Once the fault occurrence information, which is generated using the distance value provided from the relay 310, is provided from the generating unit 320 and the lightning confirmation information is provided from the receiver 330, the parser 340 can generate the fault analysis information by using the fault occurrence information only, without using the comprehensive lightning information, since no fault has occurred in the power transmission line by lightning.

The display 350 displays the fault analysis information including information about when and where a fault occurred by lightning in the power transmission line. Here, a user can check when and where the fault occurred by viewing the display 350 and deal with the fault occurred in the power transmission line by using this.

The distance relay storage 360 stores data that is required for a distance relay and data that is generated for the distance relay. That is, the distance relay storage 360 can store the distance value, which is determined by the relay 310, and store the fault occurrence information, which is generated by the generating unit 320. The distance relay storage 360 can store the comprehensive lightning information, which is received from the receiver 330, and the error value and the fault analysis information, which are generated by the parser 340. Moreover, the distance relay storage 360 provides data that is needed according to the requests by the generating unit 320, the parser 340 and the display 350.

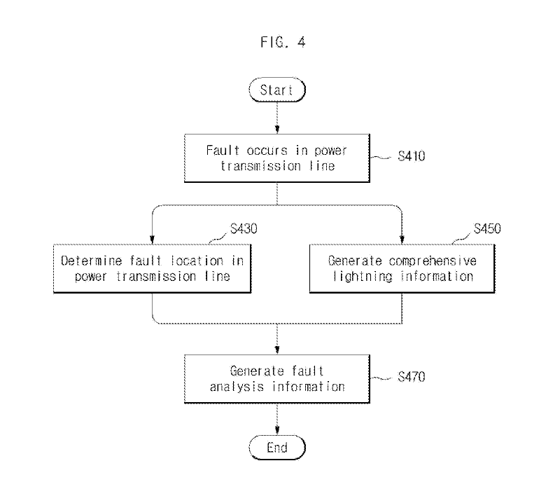

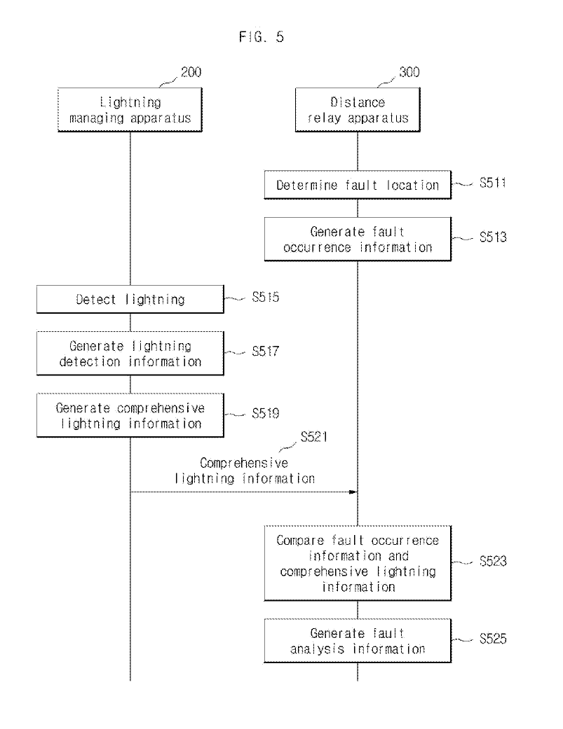

A method for processing a distance relay according to an embodiment of the present invention will be briefly described with reference to FIG. 4, which is a flowchart briefly illustrating a method for processing a distance relay in accordance with an embodiment of the present invention.

Referring to FIG. 4, a fault occurs in a power transmission line by lightning (S410).

Once the fault occurs in the power transmission line, the distance relay processing system 100 determines a fault location in the power transmission line (S430). That is, the distance relay apparatus 300 of the distance relay processing system 100 determines the fault location in the power transmission line by using the relay 310 and generates fault occurrence information.

If lightning strikes, the distance relay processing system 100 detects the lightning (S450). In other words, the lightning managing apparatus 200 in the distance relay processing system 100 detects the lightning by using the lightning detector 210 and generates comprehensive lightning information. Then, the lightning managing apparatus 200 transfers the comprehensive lightning information to the distance relay apparatus 300.

The distance relay processing system 100 generates fault analysis information by using the fault occurrence information and the comprehensive lightning information (S470). That is, the distance relay apparatus 300 of the distance relay processing system 100 generates the fault analysis information by using the fault occurrence information, which determines a fault location in the power transmission line, and the comprehensive lightning information, which is received from the lightning managing apparatus 200.

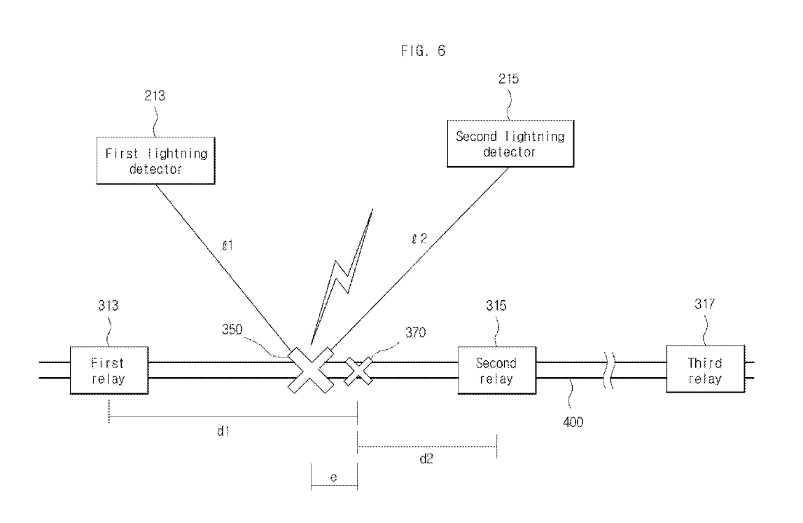

The method for processing a distance relay according to an embodiment of the present invention will be described in more detail with reference to FIG. 5, which is a flowchart illustrating, in detail, the method for processing a distance relay in accordance with an embodiment of the present invention.

Referring to FIG. 5, the distance relay apparatus 300 in the distance relay processing system 100 determines a fault location in the power transmission line (S511). In a more detailed example, among the first to fourth relays 313, 315, 317 and 319, which are included in the distance relay apparatus 300, at least one relay 310 that is connected to a power transmission line where a fault occurred generates a distance value by determining the fault location in the power transmission line.

The distance relay apparatus 300 of the distance relay processing system 100 generates fault occurrence information by using the determined fault location (S513). That is, the generating unit 320 of the distance relay apparatus 300 generates the fault occurrence information by analyzing and calculating the distance value provided from the relays 310. Here, the fault occurrence information includes transmission fault time information and transmission fault location information. The transmission fault time information is time information about when a fault occurred in the power transmission line, and the transmission fault location information is location information about where the fault occurred in the power transmission line.

The lightning managing apparatus 200 in the distance relay processing system 100 generates lightning detection information by detecting lightning (S515 and S517). Among the first to fourth lightning detectors 213, 215, 217 and 219, which are included in the lightning managing apparatus 200, at least one lightning detector 210 that has detected lightning generates the lightning detection information. The lightning detector 210 transfers the generated lightning detection information to the processor 220 of the lightning managing apparatus 200.

The lightning managing apparatus 200 in the distance relay processing system 100 generates comprehensive lightning information by using the lightning detection information (S519). In other words, the processor 220 of the lightning managing apparatus 200 generates the comprehensive lightning information by analyzing and calculating the lightning detection information provided from at least one of the lightning detector 210. In one example, the processor 220 determines when the lightning occurred by using a distance between a plurality of lightning detector 210 and the distance relay processing system 100 and time in which a plurality of lightning detection information are received and also determines where the lightning occurred by using location information included in the plurality of lightning detection information so that the processor 220 can generate the comprehensive lightning information. Here, the comprehensive lightning information includes information about when lightning has occurred, information about where lightning has occurred and information about the magnitude of current in the lightning.

The lightning managing apparatus 200 in the distance relay processing system 100 transfers the comprehensive lightning information (S521). That is, the transmission unit 240 of the lightning managing apparatus 200 transfers the comprehensive lightning information, which is generated by the processor 220, to the receiver 330 of the distance relay apparatus 300. Here, the receiver 330 of the distance relay apparatus 300 receives the comprehensive lightning information from the transmission unit 240 of the lightning managing apparatus 200.

The distance relay apparatus 300 of the distance relay processing system 100 compares the fault occurrence information with the comprehensive lightning information (S523). The parser 340 of the distance relay apparatus 300 generates an error value by comparing the fault occurrence information, which is generated by the generating unit 320, with the comprehensive lightning information, which is provided from the receiver 330. The reason why the fault occurrence information is compared with the comprehensive lightning information is that a fault location in the power transmission line where a fault has occurred has to be determined accurately because an error may occur in the fault occurrence information, which is determined by the relay 310, due to an interaction between its self-circuit and another circuit when the fault occurs in the power transmission line.

The distance relay apparatus 300 of the distance relay processing system 100 generates fault analysis information (S525). The parser 340 of the distance relay apparatus 300 generates the fault analysis information by removing the error value from the fault occurrence information. Here, the fault analysis information includes lightning transmission fault location information and lightning transmission fault time information representing where and when a fault has occurred due to lightning in the power transmission line.

Then, the display 350 of the distance relay processing system 100 displays the fault analysis information, which represents where and when the fault has occurred in the power transmission line.

The method for processing a distance relay according to an embodiment of the present invention will be described by referring to an example shown in FIG. 6, which illustrates the example of a lightning detector and a relay in a distance relay processing system in accordance with an embodiment of the present invention.

In the following description, it shall be assumed that a fault occurs at a reference numeral 350 in a power transmission line 400 as lightning strikes, as shown in FIG. 6. Since the lightning has struck, the first and second lightning detectors 213 and 215 detect the lightning and generate first and second lightning detection information l1 and l2, respectively. The first and second lightning detectors 213 and 215 provide the first and second lightning detection information l1 and l2, respectively, to the processor 220 of the lightning managing apparatus 200. The processor 220 generates comprehensive lightning information by determining the location 350, which is struck by the lightning, the time when it occurred and the magnitude of the lightning by use of the first and second lightning detection information l1 and l2. Here, since the comprehensive lightning information is generated by the first and second lightning detectors 213 and 215, each of which detects the lightning, the location 350 at which the lightning has struck can be accurately determined.

Since a fault occurred in the power transmission line 400, first and second relays 313 and 315 generate first and second distance values d1 and d2 by determining a location 370 at which the fault occurred. The first relay 313 generates the first distance value d1 because it determines that the magnitude of impedance determined by the interaction between its self-circuit and another circuit is smaller than that of impedance to the fault location. The second relay 315 generates the second distance value d2 because it determines that the magnitude of impedance determined by the interaction between the self-circuit and another circuit is greater than that of the impedance to the fault location.

The generating unit 320 generates fault occurrence information 370 by using the first and second distance values d1 and d2, which are provided from the first and second relays 313 and 315. The generated fault occurrence information 370 includes location information, instead of the actual fault location where the fault occurred, which is incorrectly determined due to the interaction between the self-circuit and another circuit.

Then, the parser 340 generates an error value e by comparing the comprehensive lightning information and the fault occurrence information 370. Then, the parser 340 generates fault analysis information including the actual fault location 350 where the fault occurred, by removing the error value e from the fault occurrence information 370.

Therefore, the distance relay processing system 100 according to an embodiment of the present invention can quickly determine the fault location in the power transmission line accurately by using the comprehensive lightning information provided from the lightning managing apparatus 200.

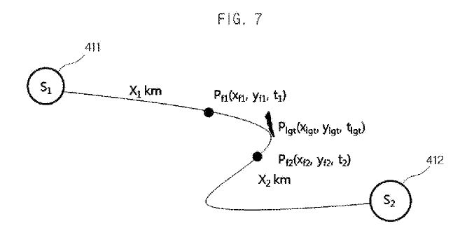

FIG. 7 is an example illustrating a method for processing a distance relay in which a distance relay apparatus determines a fault location in accordance with another embodiment of the present invention.

Described hereinafter with reference to FIG. 7 is an example of how an actual fault location is determined by a distance relay apparatus and a lightning managing apparatus when lightning has occurred and a fault has occurred in a power transmission line.

Firstly, the fault location by lightning is determined by a distance relay 411, 412 as follows.

Using the property that impedance of a conductor on the power transmission line is proportional to distance, the distance relay 411, 412 detects the location where fault has occurred due to lightning based on the distances to substations S1, S2 where the distance relays 411, 412 are installed.

The distance relay 411, 412 computes the impedance from the substation to the fault location by using voltage measured at the substation and current information of the power transmission line.

$$Z = {Z}_{l} + {Z}_{fault} = \frac{V}{{I}_{fault}}$$

The impedance Z computed as expressed above includes impedance at the fault location in addition to the impedance of the power transmission line and includes an error on the fault location that is presumed due to measurement errors of voltage and current. Since the fault location near the substation encompasses a large error, the distance relay is mostly used to detect the fault location within between 30% and 70% of the length of the entire power transmission line from the distance relay.

Since one power transmission line connects two substations with each other, the error can be reduced by combining the fault location information of at least two distance relays 411, 412.

The distance relay generates the fault location information, which indicates the fault location, by including distance values based on the S1 substation and the S2 substation.

Said fault location information is expressed with time information of when the fault has occurred.

The lightning managing apparatus generates lightning detection information.

A lightning location system measures real-time lightning information that occurs independently of the power transmission line and the distance relay and provides lightning detection information that includes longitudinal and latitudinal coordinates and occurrence time (t_{lgt}).

The distance relay 411, 412 detects the fault location based on a relative distance from the substation. However, since the power transmission line is not always straight, the comprehensive lightning information and the fault location information of the distance relay are processed as unit information that can be compared with each other.

Power transmission information of the substation includes location information of pylon, including longitude and latitude,

In accordance with an embodiment of the present invention, an exact lightning fault location can be detected by comparing the location information of the pylon with the comprehensive lightning information and the fault location information of the distance relay.

That is, the distance relay apparatus generates the comprehensive lightning information by detecting lightning detection information that is occurred in the same time slot as the fault occurrence information and is closest to the fault location range, by using lightning detection information that includes lightning occurrence location information and lightning occurrence time information provided by a plurality of lightning detectors.

The comprehensive lightning information (P_{lgt}) in accordance with an embodiment of the present invention is expressed as P_{lgt}(X_{lgt}, Y_{lgt}, t_{lgt}).

Here, X_{lgt} is a latitude coordinate, and Y_{lgt} is a longitude coordinate, and t_{lgt} is occurrence time information.

Referring to FIG. 7, the fault location detected by the distance relays 411, 412 located at the substations S1, S2 on either end of the transmission line detects a fault point (P_{f1}) by the distance relay 411 of S₁ and a fault point (P_{f2}) by the distance relay 412 of S₂, as described below.

P_{f1}(X_{f1}, Y_{f1}, t₁) is the fault location information detected by the distance relay at the substation S₁, and P_{f2}(X_{f2}, Y_{f2}, t₂) is the fault location information detected by the distance relay at the substation S₂.

X₁ is the fault location [km from S₁] detected by the distance relay at the substation S₁, and X₂ is the fault location [km from S₂] detected by the distance relay at the substation S₂. Moreover, P_{lgt}(X_{lgt}, Y_{lgt}, t_{lgt}) is the comprehensive lightning information determined to be the lightning location, which is the cause of fault, by computing the lightning detection information from a plurality of lightning detectors.

The distance relay apparatus generates the fault occurrence information, including the range of actual fault location, by using a plurality of fault location information P_{f1}(X_{f1}, Y_{f1}, t₁), P_{f2}(X_{f2}, Y_{f2}, t₂).

The range of fault location can be determined between P_{f1} and P_{f2} on the power transmission line. If the fault is related to the occurrence of lightning, each occurrence time becomes t₁=t₂=t_{lgt}. In other words, the actual lightning fault location is determined by analyzing information occurred at a same time. The distance relay apparatus searches for lightning detection information that is closest to a same time at the range of fault location computed by the fault location information detected by the distance relay 411, 412 in the same time slot. In accordance with an embodiment of the present invention, the lightning detection information that is closest to a same time is searched to be P_{lgt}.

There can be a plurality of fault points in between fault points detected and computed by a plurality of distance relays 411, 412. If there is an error detected and compute by the distance relay, it is possible that P_{f1≠}P_{f2}. Moreover, there can be a plurality of pylons, of which the position information is stored in substation data, within this section.

Therefore, according to an embodiment of the present invention, the distance relay apparatus determines the fault location by computing the closest pylon location based on the lightning detection information that is nearest to a same time within said range of fault locations from the pylon information stored in the database.

$${E}_{rr} = min ( {\sum }_{n = 1}^{m} \vert {P}_{lgt} - {P}_{tn} \vert )$$

whereas Pₜₙ is the location of pylon.

Most of the lightning that occurs on the power transmission line tends to be concentrated in an upper portion of the pylon which is higher than the surroundings, and thus the fault location can be determined by computing the location of the pylon that is nearest to the location where the lightning occurred within the fault area detected by the distance relay.

The method for processing a distance relay according to an embodiment of the present invention can be tangibly implemented in a computer-readable medium that stores a program of instructions executable by a computer, etc. The computer-readable medium can include each of program instructions, data files and data structures, or a combination of the ones above.

The program of instructions that are written in the computer-readable medium can be specially designed and configured for the present invention, or can be those available, which are generally understood by those of ordinary skill in the field of computer software. The computer-readable medium can be, for example, a hard disk, floppy disk, magnetic media such as magnetic tape, CD-ROM, optical media such as DVD, magneto-optical media such as a floptical disk and hardware device such as a ROM, RAM and flash memory, which are configured to store and perform the program of instructions. In addition to the above, the computer-readable medium can be a program of instructions and a ray of light including a carrier wave that sends a signal specifying the data structure, or can be a transmission medium such as a metal line and waveguide. Examples of the program of instructions can include a machine code, such as those created by a compiler, as well as a high-level language code executable by the computer using an interpreter.

The hardware device mentioned above can be configured to work as one or more of software modules to perform operations of the present invention.

While the ideas of the present invention have been described in detail with reference to particular embodiments, the embodiments are for illustrative purposes only and shall not limit the present invention. It is to be appreciated that those skilled in the art can change or modify the embodiments without departing from the scope and ideas of the present invention.

What is claimed is:

1. A distance relay processing system comprising:
a distance relay apparatus configured to generate fault occurrence information including fault time information and range of fault location of a power transmission line by analyzing a distance value provided by a plurality of relays; and
a lightning managing apparatus configured to generate lightning detection information including lightning occurrence time information and lightning current magnitude information provided by a plurality of lightning detectors,
wherein the distance relay apparatus is configured to:
detect lightning detection information that is occurred in a same time slot as the fault occurrence information and is nearest to the range of fault location, by analyzing lightning detection information including lightning occurrence time information and lightning occurrence location information provided by a plurality of lightning detectors;
generate comprehensive lightning information including location information of said nearest lightning detection information;
detect a location of pylon that is nearest to the comprehensive lightning information from database; and
generate fault analysis information configured to compute the detected location of pylon as a fault location.

2. The distance relay processing system of claim 1, wherein the lightning managing apparatus is configured to transfer the comprehensive lightning information to the distance relay apparatus at every transmission time,
whereas the transmission time is a time configured for transferring the comprehensive lightning information to the distance relay apparatus and is set by the lightning managing apparatus.

3. A distance relay processing method for a distance relay apparatus to control a fault location, the distance relay apparatus performing the steps of:
generating fault occurrence information including fault time information and range of fault location, by analyzing a distance value received from a plurality of relays;
detecting lightning detection information that is occurred in a same time slot as the fault occurrence information and is nearest to the range of fault location, by analyzing lightning detection information including lightning occurrence time information and lightning occurrence location information provided by a plurality of lightning detectors;
generating comprehensive lightning information including location information of said nearest lightning detection information; and
detecting a location of pylon that is nearest to the comprehensive lightning information from database, and generating fault analysis information configured to compute the detected location of pylon as a fault location.

4. A nontemporary recorded medium having a program written therein, the program embodied with instructions executable in the distance relay processing system and readable by the distance relay processing system in accordance with the method of claim 3.
